(19) United States
(12) Patent Application Publication
(10) Pub. No.: US 2025/0349658 A1
(43) Pub. Date: Nov. 13, 2025

(54) ADHESION OF A PACKAGE COMPONENT TO A HEAT SINK

(71) Applicant: Taiwan Semiconductor Manufacturing Company, Ltd., Hsin-Chu (TW)

(72) Inventors: Chih-Chien Pan, Taipei City (TW); Pu Wang, Hsinchu City (TW); Li-Hui Cheng, New Taipei City (TW)

(21) Appl. No.: 19/279,258

(22) Filed: Jul. 24, 2025

Related U.S. Application Data
(63) Continuation of application No. 18/646,458, filed on Apr. 25, 2024.
(60) Provisional application No. 63/624,913, filed on Jan. 25, 2024.

(51) Int. Cl. H01L 23/367; H01L 21/48; H01L 23/00; H01L 23/373; H01L 25/065

(52) U.S. Cl. CPC H01L 23/3675; H01L 21/4882; H01L 23/3736; H01L 24/16; H01L 24/32; H01L 24/73; H01L 25/0655; H01L 2224/16225; H01L 2224/32225; H01L 2224/73204; H01L 2924/1815

(57) ABSTRACT

A package structure is provided. The package structure includes a substrate, a package component bonded to the substrate, a lid disposed over the package component and the substrate, and an interface structure sandwiched between the package component. The package component includes a first die, a second die laterally spaced apart from the first die by an underfill, and a molding compound adjacent the first die and the second die. The interface structure includes an adhesive layer disposed over the underfill and the molding compound, and a thermal interface material (TIM) layer over the adhesive layer, the first die and the second die.

### PRIORITY DATA

This application is a continuation application of U.S. patent application Ser. No. 18/646,458, filed Apr. 25, 2024, which claims the benefit of U.S. Provisional Application No. 63/624,913, filed Jan. 25, 2024, each of which is hereby incorporated by reference in its entirety.

### BACKGROUND

In some Three-Dimensional Integrated Circuits (3DIC), device dies are bonded to a package substrate to form a package. The heat generated by the device dies during operation needs to be dissipated to prevent performance degradation or even physical damage. To dissipate heat, a metal lid may be bonded the package substrates to engage the device dies. Device dies may experience warpage due to temperature variation. Warpage may put a strain on the adhesion between the devices and the metal lid.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a package structure, according to various aspects of the present disclosure.

FIGS. 2-8 illustrate fragmentary cross-sectional views or top views of a work-in-progress (WIP) structure going through various steps of the method in FIG. 1, according to various aspects of the present disclosure.

FIG. 9 illustrates a flowchart of a method for forming a package structure, according to various aspects of the present disclosure.

FIGS. 10-12 illustrate fragmentary cross-sectional views of a work-in-progress (WIP) structure going through various steps of the method in FIG. 9, according to various aspects of the present disclosure.

FIG. 13 illustrates a flowchart of a method for forming a package structure, according to various aspects of the present disclosure.

FIGS. 14-17 illustrate fragmentary cross-sectional views of a work-in-progress (WIP) structure going through various steps of the method in FIG. 13, according to various aspects of the present disclosure.

FIGS. 18-23 illustrate alternative package structures fabricated using methods described herein, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor packaging technologies were once just considered backend processes that facilitate chips to interface external circuitry. It is no longer the case. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. To provide additional structural integrity and to improve heat dissipation, a metal lid may be attached to the package structure. Dies in package component may warp during heat cycles. The die warpage puts a strain on the adhesion interface between the package structure and the metal lid. When the adhesion fails, the metal lid may partially delaminate from the package component, interrupting heat dissipation. Because a top surface of the package structure includes different material interfaces, delamination may take place at weaker adhesion interfaces.

The present disclosure provides different interface structures between the metal lid and the package structure to reduce or minimize delamination due to die warpage. In some embodiments, a package component is bonded to a front side of a substrate. The package component includes a first die, a second die laterally spaced apart from the first die by an underfill, and a molding compound adjacent the first die and the second die. An adhesive layer is selectively dispensed over top surfaces of the underfill and the molding compound. A thermal interface material (TIM) is deposited over the adhesive layer, the first die, and the second die. After the depositing of the TIM, a lid is placed over the package component and the substrate. The adhesive layer and the TIM are eventually cured. The adhesive layer adheres well to the underfill, the molding compound, and the TIM and therefore preventing delamination. In some alternative embodiments, one or more metal layers may be deposited over the package component or the metal lid to prevent delamination.

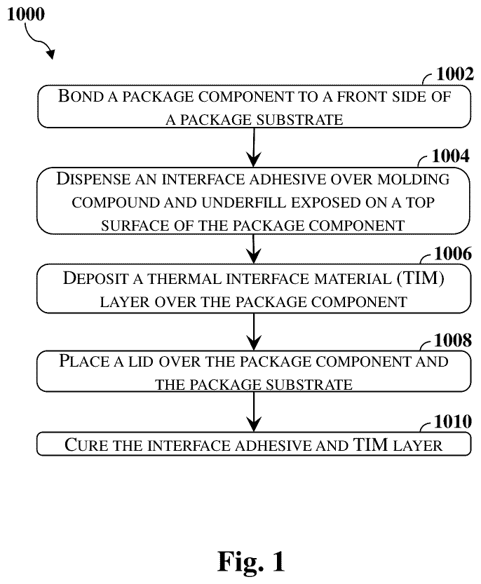

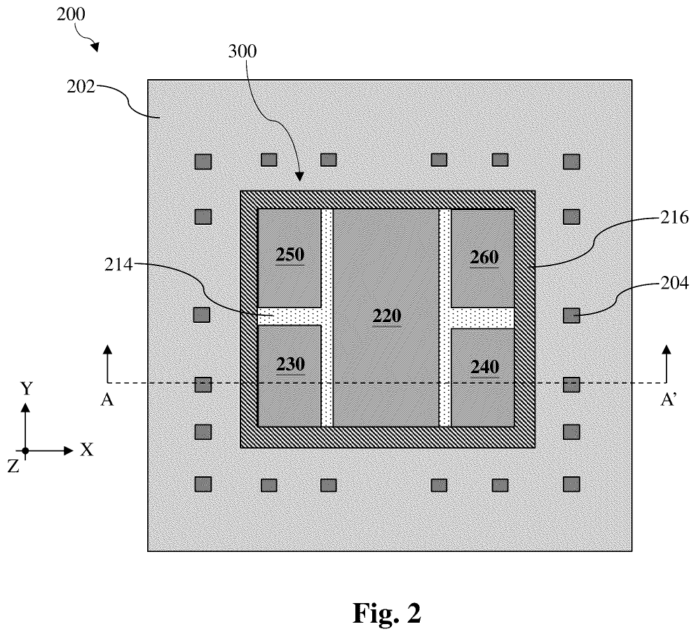

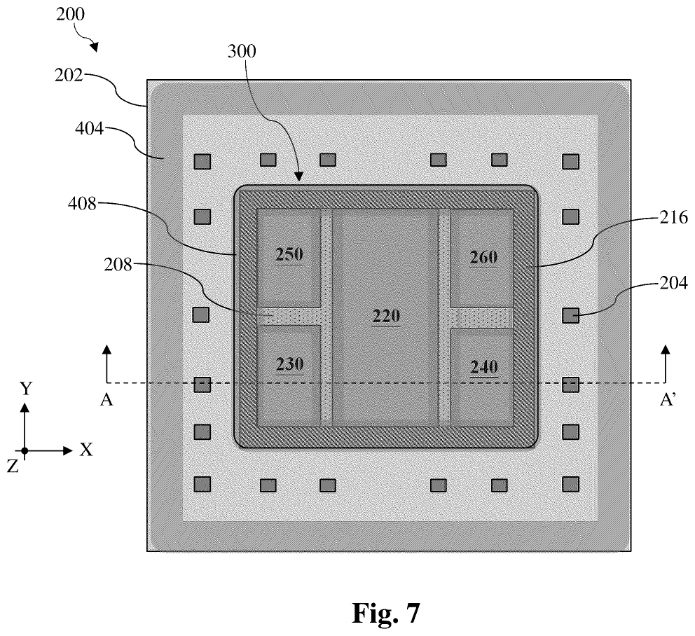

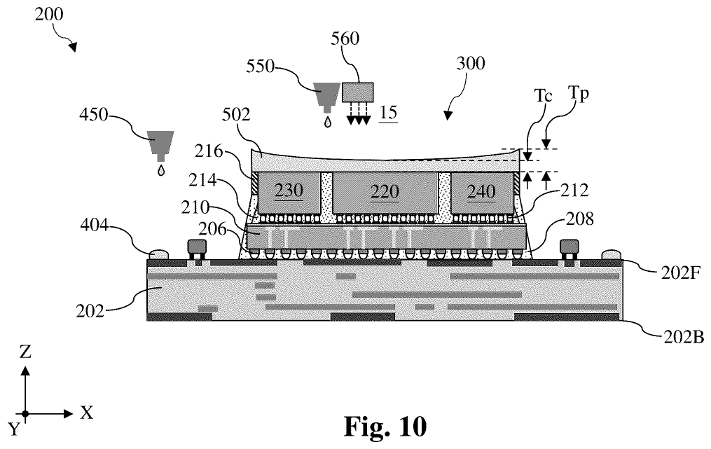

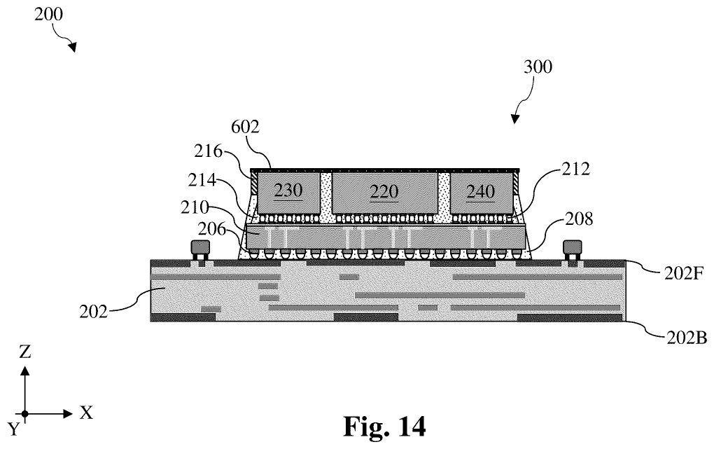

The various aspects of the present disclosure will now be described in more detail with reference to the figures. In that regard, FIGS. 1, 9 and 13 are flowcharts illustrating methods 1000, 1100 and 1200 of forming a package structure on a work-in-progress (WIP) structure 200 (shown in FIGS. 2-8, 10-12 and 14-17), according to various aspects of the present disclosure. Methods 1000, 1100 and 1200 are merely examples and are not intended to limit the present disclosure to what is explicitly illustrated in method 1000, 1100 or 1200. Additional steps can be provided before, during and after method 1000, 1100 or 1200, and some steps described can be replaced, eliminated, or moved around for additional embodiments of the method. Not all steps are described herein in detail for reasons of simplicity. Method 1000 is described below in conjunction with FIG. 2-8, which are fragmentary cross-sectional views and top views of the WIP structure 200 at different stages of fabrication according to various embodiments of method 1000. Method 1100 is described below in conjunction with FIG. 10-12, which are fragmentary cross-sectional or top views of the WIP structure 200 at different stages of fabrication according to various embodiments of method 1100. Method 1200 is described below in conjunction with FIG. 14-17, which are fragmentary cross-sectional or top views of the WIP structure 200 at different stages of fabrication according to various embodiments of method 1200. Because the WIP structure 200 will be fabricated into a package structure, the WIP structure 200 may be referred to herein as a package structure 200 as the context requires. For avoidance of doubts, the X, Y and Z directions in FIGS. 2-8, 10-12, and 14-17 are perpendicular to one another. Throughout the present disclosure, unless expressly otherwise described, like reference numerals denote like features.

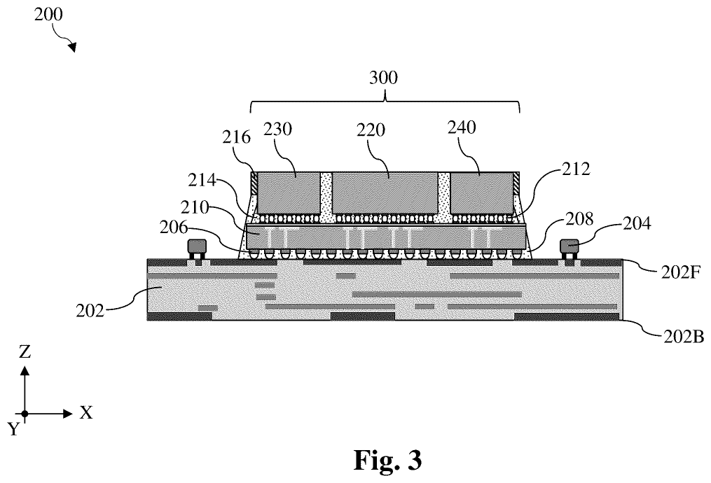

Referring to FIGS. 1, 2 and 3, method 1000 includes a block 1002 where a package component 300 is bonded to a front side surface 202F of a package substrate 202. FIG. 2 illustrates a schematic top view of the package component 300 over the package substrate 202. FIG. 3 illustrates a cross-sectional view along cross-section A-A′ in FIG. 2. In some embodiments, the package substrate 202 may include a printed circuit board (PCB) or the like. Reference is made to FIG. 3. In order to electrically couple to the package component 300, the package substrate 202 may include a plurality of contact pads over the front side surface 202F. To electrically couple to solder features over the back side surface 202B, the package substrate 202 may also include a plurality of contact pads or under bump metallization (UBM) features over the back side surface 202B. At least one passive component 204 may be bonded on the package substrate 202. The at least one passive component 204 may include a capacitor or a resistor. The package component 300 is a multi-die package (or multi-chip package) that may include more than one device die. A device die may also be referred to as a die or a chip. In the depicted embodiment shown in FIGS. 2 and 3, the package component 300 includes a first die 220, a second die 230, a third die 240, a fourth die 250, a fifth die 260, and an interposer 210. In some embodiments represented in FIG. 2, each of the first die 220, the second die 230, the third die 240, the fourth die 250, and the fifth die 260 is bonded to the interposer 210 by way of a plurality of micro-bumps 212. The space between the interposer 210 and each of the first die 220, the second die 230, the third die 240, the fourth die 250, and the fifth die 260 230 may be filled with a first underfill 214. The first die 220, the second die 230, the third die 240, the fourth die 250, and the fifth die 260 are disposed side-by-side over the interposer 210. To provide structural integrity and to improve stress absorption, upper edges of the package component 300 are surrounded by a molding compound 216. Spaces among the first die 220, the second die 230, the third die 240, the fourth die 250, and the fifth die 260 may be filled by the first underfill 214. The molding compound 216 may also be referred to as an encapsulation layer 216. The package component 300 further includes a plurality of connection features 206 to interface the package substrate 202. In some embodiments, the plurality of connection features 206 may include controlled collapse chip connection (C4) bumps or other solder bumps. The space between the package component 300 and the front side surface 202F of the package substrate 202 may be filled with a second underfill 208. In some embodiments represented in FIG. 2, the second underfill 208 may wrap around sidewalls of the interposer 210 and sidewalls of the first underfill 214. The molding compound 216 may be disposed on and in direct contact with the second underfill 208.

The interposer 210 may include a semiconductor material or glass. In one embodiment, the interposer 210 includes silicon (Si). In some alternative embodiments, the interposer 210 includes silicon germanium (SiGe) or silicon carbon (SiC). Each of the first die 220, the second die 230, the third die 240, the fourth die 250, and the fifth die 260 may be a system-on-chip (SoC) die, a logic die, an application specific integrated circuit (ASIC) die, or a high bandwidth memory (HBM) die. In one embodiment, the first die 220 is an SoC die and each of the second die 230, the third die 240, the fourth die 250, and the fifth die 260 is an HBM die. Each of the first die 220, the second die 230, the third die 240, the fourth die 250, and the fifth die 260 may include a plurality of transistors, such as planar transistors, fin-type field effect transistors (FinFETs), gate-all-around (GAA) transistors, nanowire transistors, nanosheet transistors, or other multi-gate transistors. The first underfill 214 and the second underfill 208 may include polymer or epoxy. The molding compound 216 may include a base material and fillers embedded in the base material. In some implementations, the base material of the molding compound 216 may include polymer, resin or epoxy and the fillers may include spherical particles of silicon oxide (silica) or aluminum oxide.

Reference is made to FIG. 2, which provides a top view of the package component 300. In some embodiments represented in FIG. 2, spaces among the first die 220, the second die 230, the third die 240, the fourth die 250, and the fifth die 260 may be filled with the first underfill 214 and an upper portion of the package component 300 may be surrounded by the molding compound 216. Each of the first die 220, the second die 230, the third die 240, the fourth die 250, and the fifth die 260 may have a flip chip configuration with their back sides of their device substrates exposed on the top surface of the package component 300. In some implementations, the device substrates may include silicon (Si). As a result, different materials may be exposed on a top surface of the package component 300. The molding compound 216 exposed on the top surface of the package component 300 may include polymer, resin, epoxy, silicon oxide (silica), aluminum oxide, or a combination thereof. The first underfill 214 exposed on the top surface of the package component 300 may include polymer or epoxy.

At block 1002, the package component 300 is placed over the package substrate 202 such that the connection features 206 are vertically aligned with the contact pads on the front side surface 202F of the package substrate 202. A reflow process is performed such that the connection features 206 electrically couple the interposer 210 of the package component 300 to the package substrate 202. After the reflow process, a liquid precursor of the second underfill 208 is allowed to fill the gap between the interposer 210 and the front side surface 202F of the package substrate 202 through capillary action. The package substrate 202 and the package component 300 shown in FIGS. 2 and 3 may be collectively referred to as a work-in-progress (WIP) structure 200. During operations at various blocks of method 100, components may be added to the WIP structure 200 and the present disclosure will continue to refer to the resulting structure as the WIP structure 200.

Referring to FIGS. 1 and 4-5, method 1000 includes a block 1004 where an interface adhesive 402 is selectively dispensed over the molding compound 216 and the first underfill 214 exposed on a top surface of the package component 300. As described above in conjunction with FIG. 2, the top surface of the package component 300 includes different exposed material surfaces. It has been observed through experimentation and quality control data that a thermal interface material (TIM) does not adhere well to surfaces of the molding compound 216 or the first underfill 214. The interfaces between the TIM and the molding compound 216 and between the TIM and the first underfill 214 may become weak spots with less than ideal adhesion. When the package component 300 is subject to thermal cycles, the first die 220, the second die 230, the third die 240, the fourth die 250, and the fifth die 260 may warp and unwarp, thereby exerting stress at the interface between the top surface of the package component 300 and the TIM. The weak spots tend to fail prematurely and result in delamination of the TIM from the package component 300. Such delamination may disrupt the heat conduction path and hinder dissipation of heat from the package component 300.

At block 1004, the interface adhesive 402 is selectively deposited over the exposed surfaces of the molding compound 216 and the first underfill 214. In some embodiments, the selective dispensing may be performed using a precision dispensing system. The precision dispensing system includes a precision dispensing head 400 that dispenses or injects the interface adhesive 402 in a gel form, a liquid form or a paste form. A stepper of the precision dispensing system may move the precision dispensing head 400 precisely over exposed surfaces of the molding compound 216 and the first underfill 214 and a suitable amount of the interface adhesive 402 is dispensed via the precision dispensing head 400. In some embodiments, the interface adhesive 402 may include a die attach film (DAF) gel, silicone, polyimide (PI), or epoxy. Because the primary function of the interface adhesive 402 is adhesion, not heat dissipation/conduction, the interface adhesive 402 does not include highly thermally conductive materials such as beryllium oxide, aluminum oxide, zinc oxide, aluminum nitride, hexagonal boron nitride, metal (i.e., silver, copper, tin, or indium), diamond, graphene, carbon nanotubes, or graphite. The lack of these highly thermally conductive materials allows the interface adhesive 402 to have better adhesion to the molding compound 216 or the first underfill 214 than TIM, which includes highly thermally conductive material. Moreover, the absence of these highly thermally conductive materials also allows the interface adhesive 402 to have a smaller Young's modulus than TIM that includes highly thermally conductive materials. As deposited, the interface adhesive 402 may have a thickness T. In some instances, the thickness T is between about 0.5 μm and about 30 μm.

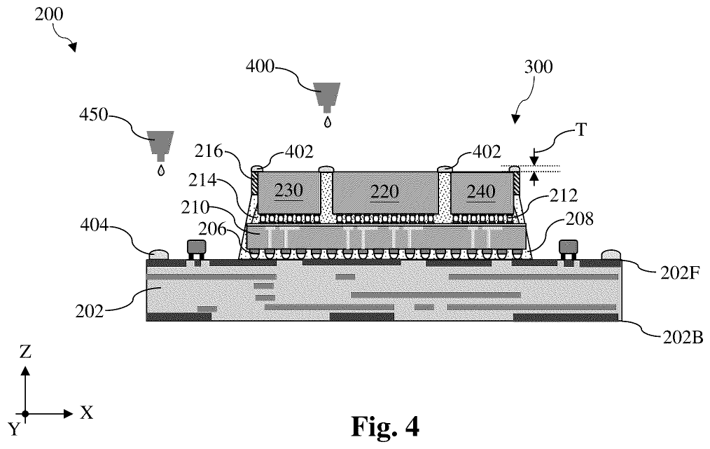

Besides the interface adhesive 402, an adhesive 404 may also be dispensed over a landing area of a lid 410 (to be described below) on the package substrate 202. Because the adhesive 404 functions to attach the lid to the top surface of the package substrate 202, the adhesive 404 is also dispensed on the top surface of the package substrate 202. In some embodiments, the adhesive 404 may include a die attach film (DAF) gel, silicone, polyimide (PI), or epoxy. In some embodiments represented in FIG. 4, the adhesive 404 may be deposited on the package substrate 202 using a dispensing system. The dispensing system includes a dispensing head 450 that dispenses or injects the adhesive 404 in a gel form, a liquid form or a paste form. A stepper of the dispensing system may move the dispensing head 450 over the landing area of the lid 410 on the package substrate 202. Compared to the interface adhesive 402 that requires precise dispensing to avoid hindering heat conduction, the adhesive 404 does not need to be precisely deposited over the landing area. For those reasons, a viscosity of the adhesive 404 may be greater than a viscosity of the interface adhesive 402. To accommodate the greater viscosity of the adhesive 404, an orifice diameter of the dispensing head 450 for the adhesive 404 is greater than an orifice diameter of the precision dispending head 400 for the interface adhesive 402.

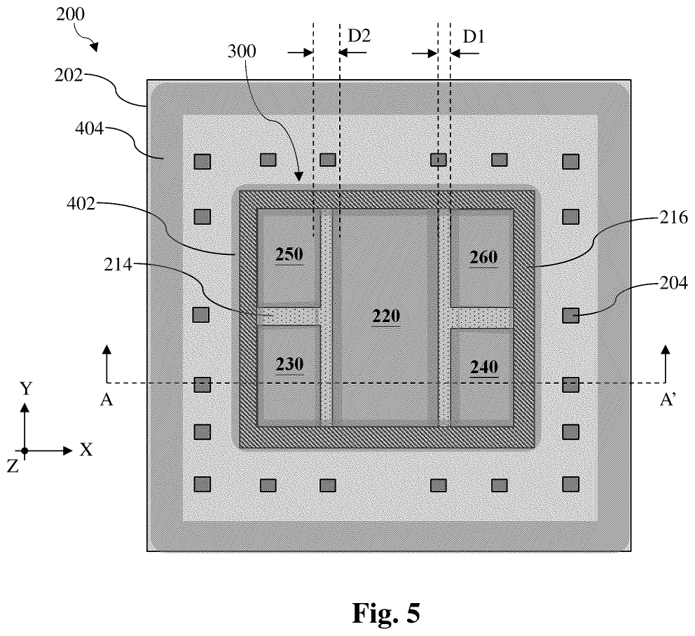

Referring to FIG. 5, the exposed first underfill 214 among two adjacent dies may have a first dimension D1. It is desired that the interface adhesive 402 dispensed at block 1004 completely cover the exposed first underfill 214 because the interface adhesive 402 adheres better to the first underfill 214 than the TIM layer 408 (to be described below). In some instances, the interface adhesive 402 over the exposed first underfill 214 should have a second dimension D2 equal to or greater than the first dimension D1.

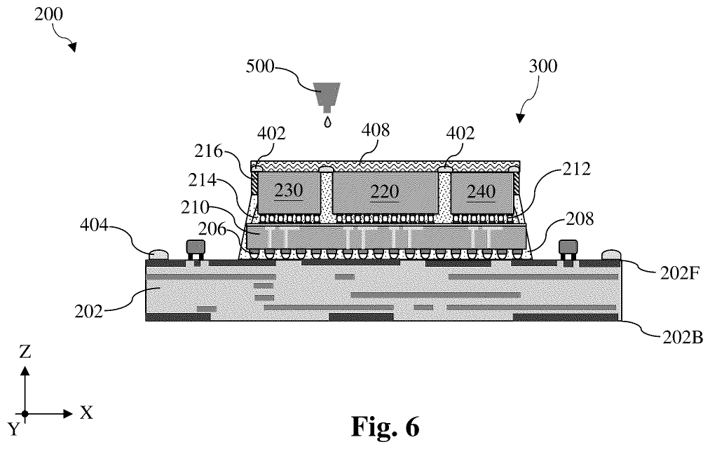

Referring to FIGS. 1 and 6-7, method 1000 includes a block 1006 where a thermal interface material (TIM) layer 408 is deposited over the package component 300. For purpose of the present disclosure, TIM refers to materials that are placed between an electronic device and a heat sink to improve heat dissipation of the electronic device. Because voids and gaps introduce air in the heat conduction path and air has low thermal conductivity, one of TIM's functions is to fill the gaps between the electronic device and the heat sink so as to reduce voids and gaps. To serve the gap filling function well, TIM or a precursor of TIM should possess reasonable flowability or flexibility. Additionally, TIM should have sufficient thermal conductivity to facilitate heat conduction. Furthermore, it is desirable that TIM has good stress absorption property to protect the electric device and prevent delamination. According to the present disclosure, at block 1006, the TIM layer 408 may be applied in a gel form, a liquid form or a paste form. In some embodiments, the TIM layer 408 may include a base material and a thermal conductive filler. In some instances, the base material for the TIM layer 408 may include silicone, resin or epoxy and the thermal conductive filler for the TIM layer 408 may include beryllium oxide, aluminum oxide, zinc oxide, aluminum nitride, hexagonal boron nitride, metal (i.e., silver, copper, tin, or indium), diamond, graphene, carbon nanotubes, or graphite. As shown in FIG. 6, the TIM layer 408 is deposited over the package component 300 using a dispensing system having a dispensing head 500, including back sides of the device substrates for the first die 220, the second die 230, the third die 240, the fourth die 250, and the fifth die 260 as well as the interface adhesive 402. Because the interface adhesive 402 has been deposited to cover the molding compound 216 and the first underfill 214, the TIM layer 408 is spaced apart from the molding compound 216 and the first underfill 214 by the interface adhesive 402. In this regard, the interface adhesive 402 serves as an interface layer between the TIM layer 408, on the one hand, and the molding compound 216 and the first underfill 214, on the other hand. In some embodiments, the TIM layer 408 may have a thickness between about 50 μm and about 150 μm.

While the adhesive 404 is described as being dispensed over the package substrate 202 at block 1004, it should be understood stood that it may also be dispensed over the package substrate 202 at block 1006 before or after the deposition of the TIM layer 408.

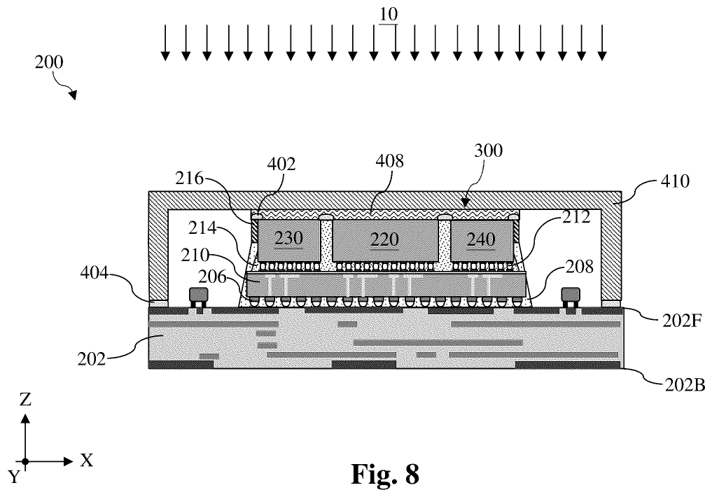

Referring to FIGS. 1 and 8, method 1000 includes a block 1008 where a lid 410 is placed over the package component 300 and the package substrate 202 to engage the adhesive 404 and the TIM 408. In some embodiments, the lid 410 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. Because the lid 410 is formed of a metal or a metal alloy, it may be referred to as a metal lid. The lid 410 has at least three functions. First, it serves as a heat sink to dissipate heat from the package component 300 by way of the TIM layer 408. Second, it provides structural rigidity to the package substrate 202 to prevent or reduce warping. Third, it creates a sealed environment to protect the package component 300. At block 1008, the lid 410 is placed over the package component 300 and the package substrate 202 such that its bottom edges engage the adhesive 404 on the package substrate 202 and its bottom surface presses on and engages the TIM layer 408. As shown in FIG. 8, because the interface adhesive 402 is precisely dispensed over the exposed molding compound 216 and first underfill 214 among the dies (i.e., the first die 220, the second die 230, the third die 240, the fourth die 250, and the fifth die 260), the TIM layer 408 engages the majority of the device substrates of the dies and the lid 410. This allows the TIM layer 408, which includes highly thermally conductive material and is more thermally conductive than the interface adhesive 402, to conduct heat from the dies to the lid 410.

Referring to FIGS. 1 and 8, method 1000 includes a block 1010 where the interface adhesive 402, the adhesive 404 and the TIM 408 are cured. In some embodiments, the interface adhesive 402, the adhesive 404 and the TIM layer 408 are thermally curable. In these embodiments, the WIP structure 200 shown in FIG. 8 may be subject to an anneal process 10 to cure the interface adhesive 402, the adhesive 404 and the TIM layer 408. In some embodiments, the anneal process 10 for curing the interface adhesive 402, the adhesive 404 and the TIM layer 408 may include a curing temperature between about 100° C. and about 200° C. and a curing time between about 1 hour and about 2 hours.

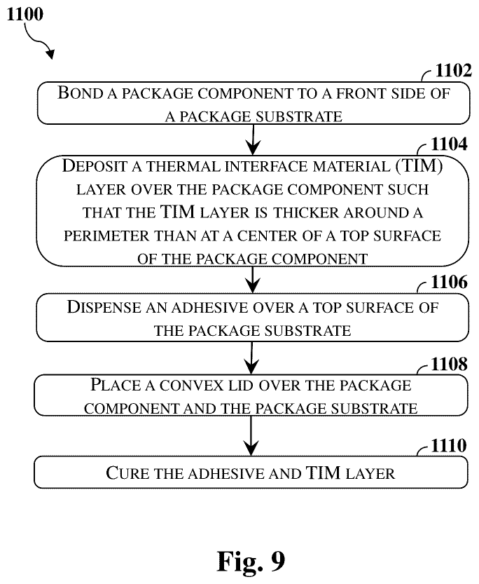

In method 1000 described above, the interface adhesive 402 is dispensed over the exposed surfaces of the molding compound 216 and the first underfill 214 to serve as an interface layer to improve adhesion between the TIM layer 408 and the molding compound 216 and the first underfill 214. Because the interface adhesive 402 is precisely dispensed, the TIM layer 408 still engages the majority of the surfaces of the dies to maintain satisfactory thermal conduction to the lid 410. Method 1100 shown in FIG. 9 is different from method 1000 in at least three aspects. First, method 1100 does not dispense any interface adhesive 402 over the package component 300. Second, a TIM layer 502 is dispensed over the package component 300 in a way that a thickness of the TIM layer 502 along a perimeter of the package component 300 is greater than that around a geometric center of the package component 300 to withstand die warpage. Third, convex lids with a convex bottom surface are used to accommodate the profile of the TIM layer 502.

Referring to FIGS. 9 and 2, method 1100 includes a block 1102 where a package component 300 is bonded to a front side surface 202F of a package substrate 202. Operations at block 1102 are substantially similar to those at block 1002 of method 1000 described above. For that reason, details of operations at block 1102, the package component 300, and the package substrate 202 are omitted for brevity.

Referring to FIGS. 9 and 10, method 1100 includes a block 1104 where a TIM layer 502 is deposited over the package component 300 such that the TIM layer 502 is thicker around a perimeter of the package component 300 than a center of a top surface of the package component 300. At block 1104, the TIM layer 502 is dispensed as a liquid, gel or paste using a dispensing system. The dispensing system includes a dispensing head 550 that dispenses or injects the TIM layer 502 (or a precursor thereof) and an ultraviolet (UV) emitter 560 to emit UV ray 15 on the dispensed TIM layer 502. A stepper of the precision dispensing system may move the dispensing head 550 and the UV emitter 560 over a top surface of the package component 300, which may be rectangular or square in a top view. In some embodiments, the precision dispending system injects more of the TIM material along a perimeter of the top surface of the package component 300 than around a geometric center of the top surface of the package component 300. As the TIM layer 502 is being deposited, the UV emitter 560 emits UV ray 15 on the TIM layer 502 to partially cure the TIM layer 502. The partial curing allows the deposited TIM layer 502 to set or maintain its shape. In some embodiments represented in FIG. 10, the TIM layer 502 has a center thickness Tc and a perimeter thickness Tp. The perimeter thickness Tp is greater than the center thickness Tc. In some instances, the perimeter thickness Tp may be between about 100 μm and about 150 μm and the center thickness Tc may be between about 30 μm and about 50 μm. In some instances, the thickness of the TIM layer 502 may increase from the center thickness Tc to the perimeter thickness Tp linearly or parobolically. Experiments and simulation results indicate that the stress caused by die warpage is greater around the perimeter of a package component than at a center of the package component. The greater perimeter thickness Tp provides more cushion to absorb the additional stress along the perimeter of the package component 300. In some embodiments, the TIM layer 502 may include a base material and a thermal conductive filler. In some instances, the base material for the TIM layer 502 may include silicone, resin or epoxy and the thermal conductive filler for the TIM layer 502 may include beryllium oxide, aluminum oxide, zinc oxide, aluminum nitride, hexagonal boron nitride, metal (i.e., silver, copper, tin, or indium), diamond, graphene, carbon nanotubes, or graphite.

Referring to FIGS. 9 and 10, method 1100 includes a block 1106 where an adhesive 404 is dispensed over the package substrate 202. As will be described below, method 1100 attaches a first convex lid 412 or a second convex lid 414 to the package component 300 and the package substrate 202. The first convex lid 412 or the second convex lid 414 engages the package component 300 by way of the TIM layer 502 and attaches to the top surface of the package substrate 202 through the adhesive 404. At block 1106, the adhesive 404 is selectively deposited over a landing area on the top surface of the package substrate 202. When the lid 410 is placed over the package substrate 202, a lower edge of the lid 410 is going to engage the adhesive 404 in the landing area. In some embodiments, the selective dispensing of the adhesive 404 may be performed using a dispensing system. The dispensing system includes a dispensing head 450 that dispenses or injects the adhesive 404 in a gel form, a liquid form or a paste form. A stepper of the dispensing system may move the dispensing head 450 precisely over the landing area. In some embodiments, the adhesive 404 may include a die attach film (DAF), silicone, polyimide (PI), or epoxy. Because the primary function of the adhesive 404 is adhesion, not heat dissipation/conduction, the adhesive 404 does not include highly thermally conductive materials such as beryllium oxide, aluminum oxide, zinc oxide, aluminum nitride, hexagonal boron nitride, metal (i.e., silver, copper, tin, or indium), diamond, graphene, carbon nanotubes, or graphite.

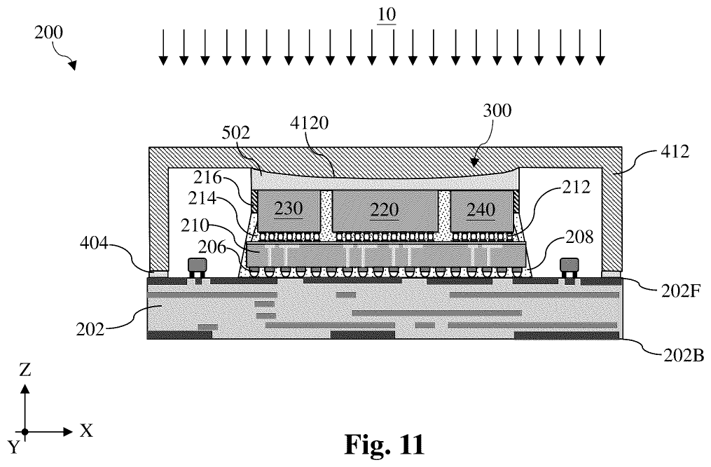

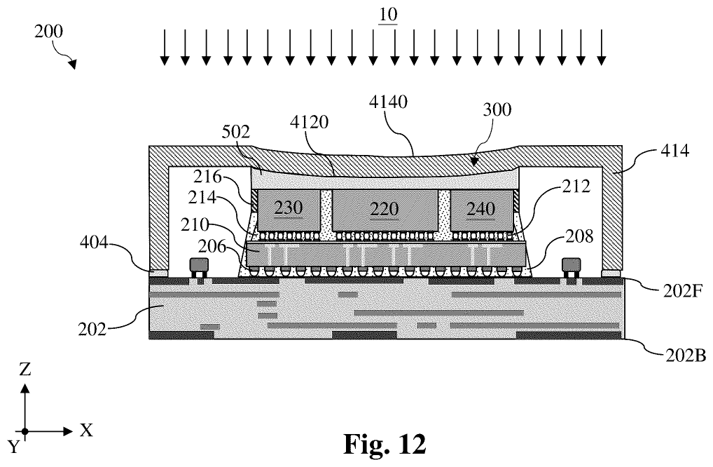

Referring to FIGS. 9, 11 and 12, method 1100 includes a block 1108 where a convex lid (a first convex lid 412 shown in FIG. 11 or a second convex lid shown in FIG. 12) is placed over the package component 300 and the package substrate 202 to engage the adhesive 404 and the TIM layer 502. In some embodiments, the convex lid is a first convex lid 412 shown in FIG. 11. In some other embodiments, the convex lid is a second convex lid 414 shown in FIG. 12. Both the first convex lid 412 and the second convex lid 414 may be formed of a metal or an alloy, such as aluminum (Al), copper (Cu), iron (Fe), nickel (Ni), cobalt (Co), or an alloy thereof. Both the first convex lid 412 and the second convex lid 414 have a convex bottom surface 4120 that protrudes from the bottom surface. Example alloys may include an aluminum-copper alloy, an iron-nickel alloy, or an iron-nickel-cobalt alloy. The first convex lid 412 includes a level/flat top surface. The second convex lid 414 includes a concave top surface 4140. At block 1108, the first convex lid 412 or the second convex lid 414 is placed over the package component 300 and the package substrate 202 such that its lower edges engage the adhesive 404 on the package substrate 202 and its convex bottom surface presses on and engages the TIM layer 502.

Referring to FIGS. 9, 11 and 12, method 1100 includes a block 1110 where the adhesive 404 and/or the TIM layer 502 are cured. In some embodiments, the adhesive 404 and the TIM layer 502 are thermally curable. In these embodiments, the WIP structure 200 shown in FIG. 11 or 12 may be subject to an anneal process 10 to cure the adhesive 404 and the TIM layer 502. In some embodiments, the anneal process 10 for curing the adhesive 404 and the TIM layer 502 may include a curing temperature between about 100° C. and about 200° C. and a curing time between about 1 hour and about 2 hours. At block 1110 the anneal process 10 fully cures the TIM layer 502 that is partially cured by the UV ray 15 at block 1104.

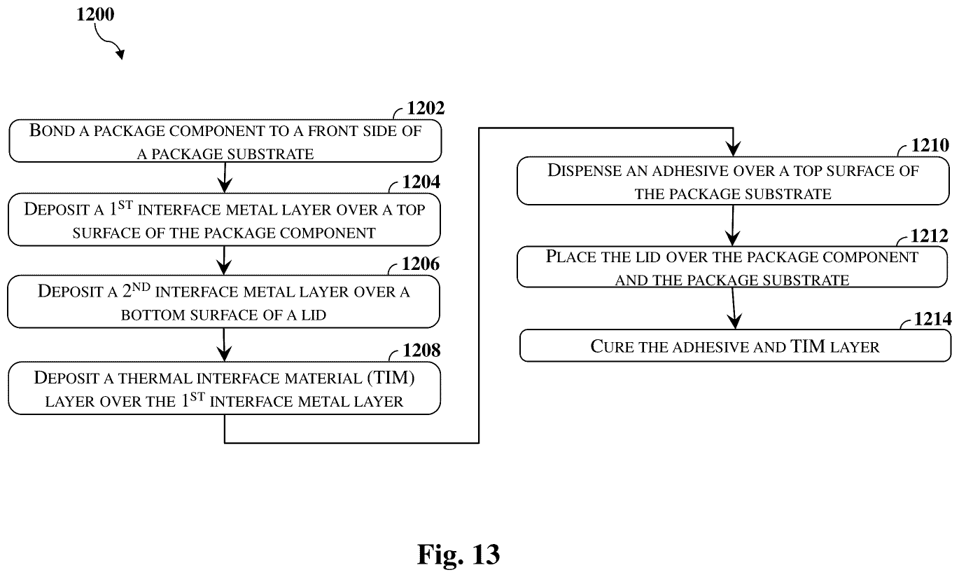

In method 1000 described above, the interface adhesive 402 is dispensed over the exposed surfaces of the molding compound 216 and the first underfill 214 to serve as an interface layer to improve adhesion between the TIM layer 408 and the molding compound 216 and the first underfill 214. Because the interface adhesive 402 is precisely dispensed, the TIM layer 408 still engages the majority of the surfaces of the dies to maintain satisfactory thermal conduction to the lid 410. Method 1200 shown in FIG. 13 is different from method 1000 in at least that method 1200 utilizes interface metal layers to improve adhesion.

Referring to FIGS. 13 and 2, method 1200 includes a block 1202 where a package component 300 is bonded to a front side surface 202F of a package substrate 202. Operations at block 1202 are substantially similar to those at block 1002 of method 1000 described above. For that reason, details of operations at block 1202, the package component 300, and the package substrate 202 are omitted for brevity.

Referring to FIGS. 13 and 14, method 1200 includes a block 1204 where a first interface metal layer 602 is deposited over a top surface of the package component 300. While not explicitly shown in the figures, the first interface metal layer 602 is deposited over the top surface of the package component 300 before the package component 300 is singulated from a wafer. Before the wafer that includes the package component 300 is diced, the first interface metal layer 602 is deposited over the wafer by physical vapor deposition (PVD). After the singulation process, each of the package component 300 includes the first interface metal layer 602 before it is mounted on the package substrate 202. In some embodiments, the first interface metal layer 602 includes a metal or metal nitride, such as silver (Ag), gold (Au), titanium (Ti), titanium nitride (TiN), copper (Cu), or tin (Sn). In an alternative embodiment, the first interface metal layer 602 is selectively deposited on the package component 300 after the package component 300 is mounted on the package substrate 202. In the alternative embodiment, a stencil may be placed over the WIP structure 200 with the top surface of the package component 300 exposed. A PVD deposition process, such as sputtering, is then performed to selectively deposit the first interface metal layer 602 on the exposed top surface of the package component 300. After the deposition, the stencil is removed. Because the first interface metal layer 602 is deposited using PVD, the first interface metal layer 602 has a thickness smaller than 2 μm, such as between about 1 μm and about 2 μm.

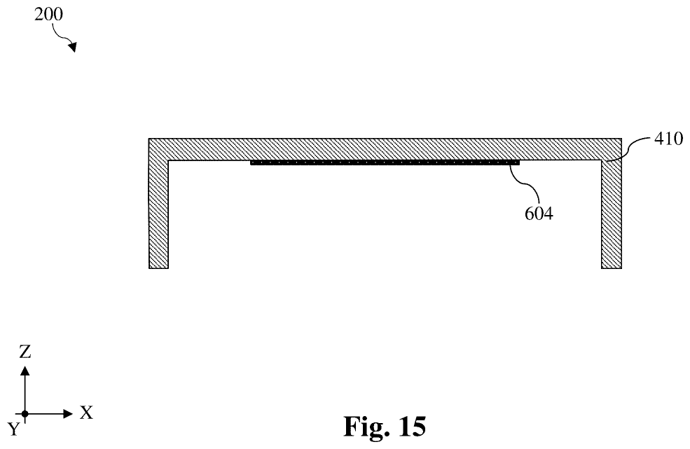

Referring to FIGS. 13 and 15, method 1200 includes a block 1206 where a second interface metal layer 604 is deposited over a bottom surface of a lid 410. A composition of the second interface metal layer 604 may be similar to that of the first interface metal layer 602. In some embodiments, the second interface metal layer 604 may include silver (Ag), gold (Au), titanium (Ti), titanium nitride (TiN), copper (Cu), or tin (Sn). In some implementations, the second interface metal layer 604 may be deposited over the bottom surface of the lid 410 using PVD or electroplating. To selectively deposit the second interface metal layer 604 over a predetermined engagement area over the bottom surface of the lid 410, a stencil may be placed over the bottom surface of the lid 410, with the engagement area exposed. A PVD deposition process or an electroplating process is then performed to deposit the second interface metal layer 604 over the engagement area. The deposited second interface metal layer 604 may have a surface area greater than the top surface of the package component 300. In some embodiments not explicitly shown in FIG. 15, the entire bottom surface of the lid 410 is coated with the second interface metal layer 604. This ensures that the second interface metal layer 604 comes between the package component 300 and the bottom surface of the lid 410. When the second interface metal layer 604 is deposited using PVD, the second interface metal layer 604 has a thickness smaller than 2 μm, such as between about 1 μm and about 2 μm. When the second interface metal layer 604 is deposited using electroplating, the second interface metal layer 604 has a thickness between about 1 μm and about 3 μm.

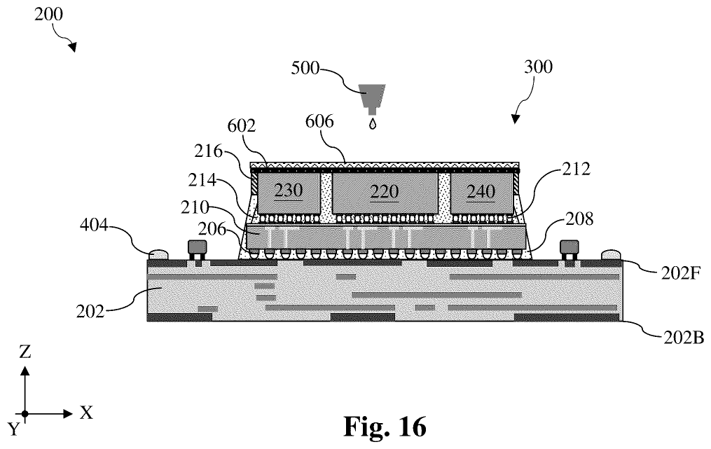

Referring to FIGS. 13 and 16, method 1200 includes a block 1208 where a TIM layer 606 is deposited over the first interface metal layer 602. At block 1208, the TIM layer 606 may be deposited over the first interface metal layer 602 in a gel form, a liquid form or a paste form. In some embodiments, the TIM layer 606 may include a base material and a thermal conductive filler. In some instances, the base material for the TIM layer 606 may include silicone, resin or epoxy and the thermal conductive filler for the TIM layer 606 may include beryllium oxide, aluminum oxide, zinc oxide, aluminum nitride, hexagonal boron nitride, metal (i.e., silver, copper, tin, or indium), diamond, graphene, carbon nanotubes, or graphite. As shown in FIG. 16, the TIM layer 606 is deposited over the first interface metal layer 602 over the package component 300 using a dispensing system having a dispensing head 500. Because the first interface metal layer 602 has been deposited to cover the package component 300, the TIM layer 606 is spaced apart from the molding compound 216, the first underfill 214, and the dies by the first interface metal layer 602. In this regard, the first interface metal layer 602 serves as an interface layer between the TIM layer 606, on the one hand, and the molding compound 216, the first underfill 214, and the dies on the other hand. In some embodiments, the TIM layer 606 may have a thickness between about 50 μm and about 150 μm. In some instances, because of the different deposition methods, the thickness of the TIM layer 606 may be about 50 to about 100 times of the thickness of the first interface metal layer 602 or the second interface metal layer 604.

Referring to FIGS. 13 and 16, method 1200 includes a block 1210 where an adhesive 404 is dispensed over the package substrate 202. As will be described below, method 1200 attaches a lid 410 to the package component 300 and the package substrate 202. The lid 410 engages the package component 300 by way of the first interface metal layer 602, the TIM layer 606 and the second interface metal layer 604 and attaches to the top surface of the package substrate 202 through the adhesive 404. At block 1210, the adhesive 404 is selectively deposited over a landing area on the top surface of the package substrate 202. When the lid 410 is placed over the package substrate 202, a lower edge of the lid 410 is going to engage the adhesive 404 in the landing area. In some embodiments, the selective dispensing of the adhesive 404 may be performed using a dispensing system. The dispensing system includes a dispensing head 450 that dispenses or injects the adhesive 404 in a gel form, a liquid form or a paste form. A stepper of the dispensing system may move the dispensing head 450 precisely over the first interface metal layer 602. In some embodiments, the adhesive 404 may include a die attach film (DAF), silicone, polyimide (PI), or epoxy. Because the primary function of the adhesive 404 is adhesion, not heat dissipation/conduction, the adhesive 404 does not include highly thermally conductive materials such as beryllium oxide, aluminum oxide, zinc oxide, aluminum nitride, hexagonal boron nitride, metal (i.e., silver, copper, tin, or indium), diamond, graphene, carbon nanotubes, or graphite.

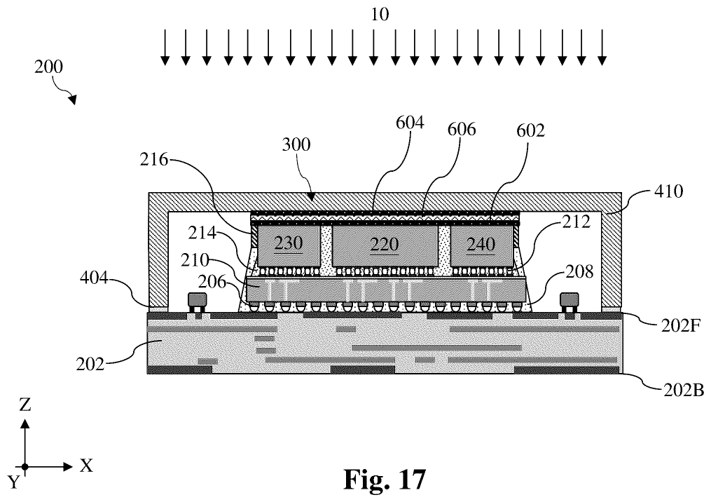

Referring to FIGS. 13 and 17, method 1200 includes a block 1212 where a lid 410 is placed over the package component 300 and the package substrate 202. At block 1212, the lid 410 that includes the second interface metal layer 604 on its bottom surface is placed over the package component 300 and the package substrate 202. As shown in FIG. 17, the lower edges of the lid 410 engage the adhesive 404 on the package substrate 202 and the second interface metal layer 604 on the bottom surface presses on and engages the TIM layer 606. The lid 410 is attached to the package substrate 202 by the adhesive 404 and is thermally coupled to the package component 300 by way of the first interface metal layer 602, the TIM layer 606, and the second interface metal layer 604. Because the first interface metal layer 602, the TIM layer 606, and the second interface metal layer 604 are all formed of highly thermally conductive materials, heat generated in the package component 300 can be dissipated through the lid 410.

Referring to FIGS. 13 and 17, method 1200 includes a block 1214 where the adhesive 404 and/or the TIM layer 606 are cured. In some embodiments, the adhesive 404 and the TIM layer 606 are thermally curable. In these embodiments, the WIP structure 200 shown in FIG. 17 may be subject to an anneal process 10 to cure the adhesive 404 and the TIM layer 606. In some embodiments, the anneal process 10 for curing the adhesive 404 and the TIM layer 606 may include a curing temperature between about 100° C. and about 200° C. and a curing time between about 1 hour and about 2 hours.

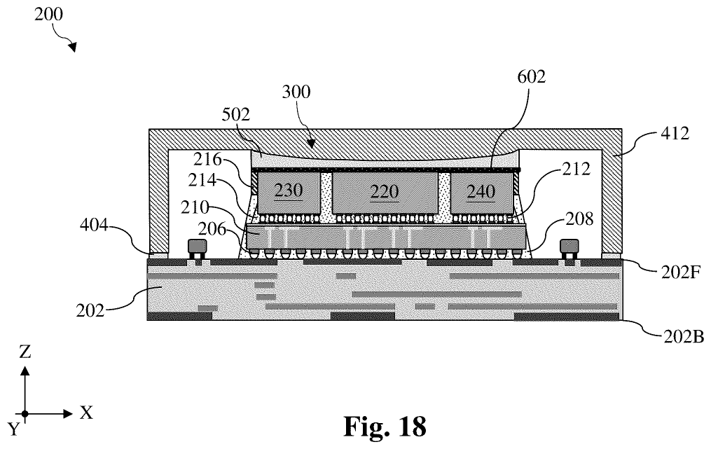

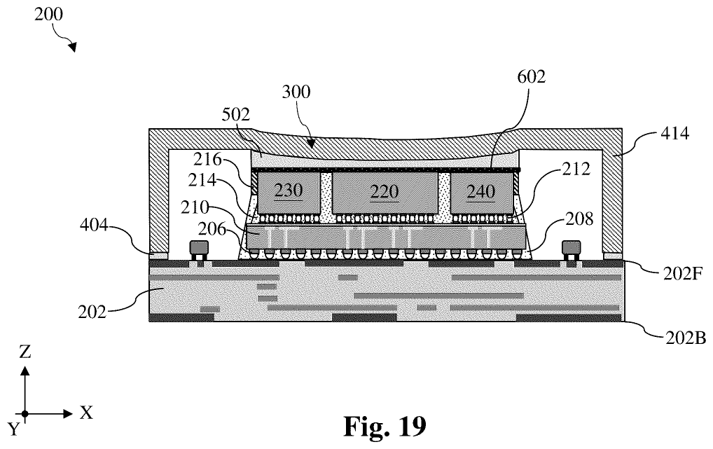

Method 1200 in FIG. 13 may be modified or combined with method 1100 or method 1000 to form alternative package structures 200 shown in FIGS. 18-23. FIGS. 18 and 19 illustrate an alternative package structure 200 where a first interface metal layer 602 is deposited over the package component 300 before TIM layer 502 is deposited over the package component 300. That is, operations at block 1204 of method 1200 are performed to the WIP structure 200 before method 1100 deposits the TIM layer 502 at block 1104. The first interface metal layer 602 in FIG. 18 may function to further improve adhesion and stress absorption between the package component 300 and the TIM layer 502. To accommodate the concave profile of the TIM layer 502, the first convex lid 412 (shown in FIG. 18) or the second convex lid 414 (shown in FIG. 19) may be placed over the WIP structure 200 to engage and accommodate the concaved profiles of the TIM layer 502.

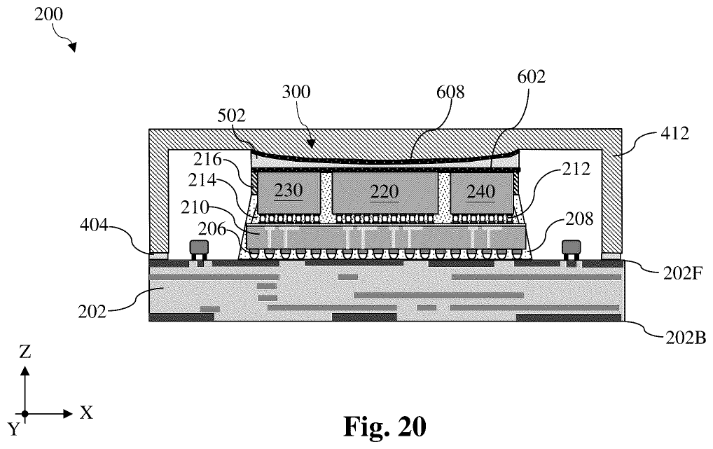

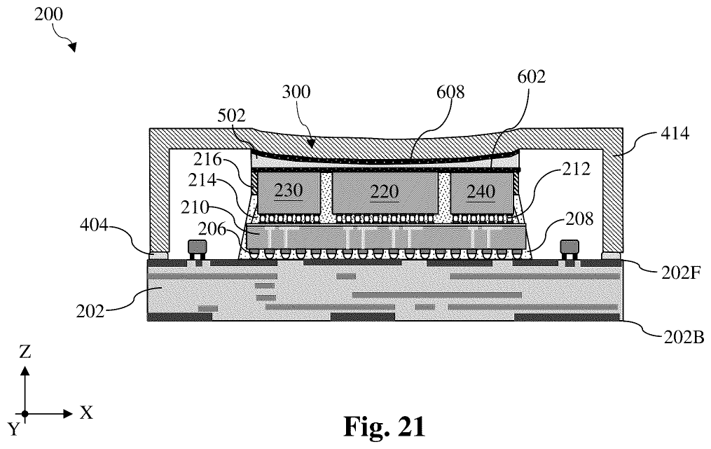

FIGS. 20 and 21 illustrate alternative package structures 200 where a first interface metal layer 602 is deposited over the package component 300 and a third interface metal layer 608 is deposited over the convex bottom surface of a convex lid before TIM layer 502 is deposited over the package component 300. The convex lid may be the first convex lid 412 shown in FIG. 20 or the second convex lid 414 shown in FIG. 21. The third interface metal layer 608 may be similar to the second interface metal layer 604 in terms of deposition methods and composition but tracks the convex shape of the bottom surface of the convex lid. That is, operations at block 1204 and block 1206 of method 1200 are performed to the WIP structure 200 before method 1100 deposits the TIM layer 502 at block 1104. Both the first interface metal layer 602 or the third interface metal layer 608 in FIG. 20 or 21 may function to further improve adhesion and stress absorption between the package component 300 and the TIM layer 502.

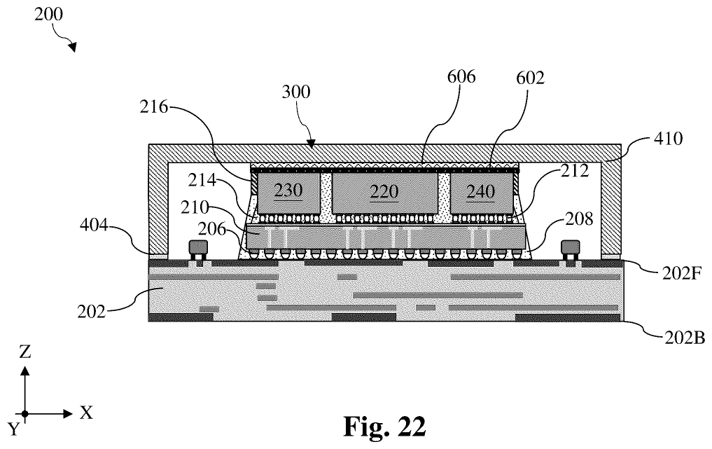

FIG. 22 illustrates yet another alternative package structure 200 where the second interface metal layer 604 is omitted and the TIM layer 606 comes in direct contact with the bottom surface of the lid 410. While the dies in the package component 300 may warp and unwarp in heat cycles to cause delamination, the lid 410 does not substantially warp in heat cycles. In some embodiments, the second interface metal layer 604 is omitted to reduce process steps.

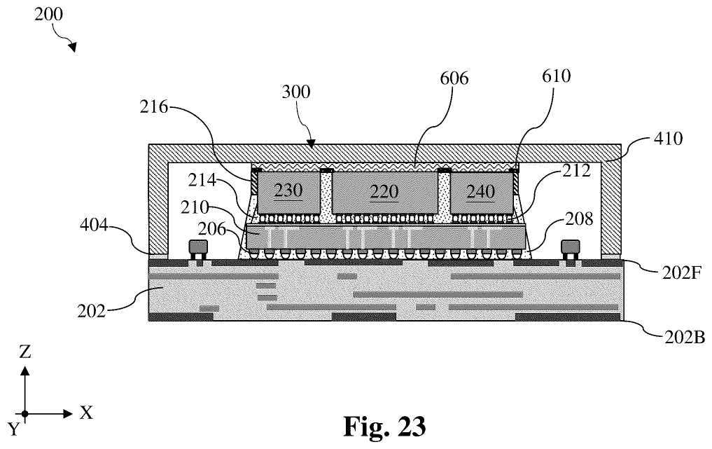

FIG. 23 illustrates still another alternative package structure 200 where the interface adhesive 402 that covers the molding compound 216 and the first underfill 214 is replaced with a fourth interface metal layer 610. To form the package structure 200 in FIG. 23, interface adhesive 402 is not selectively dispensed over the exposed surfaces of the molding compound 216 and the first underfill 214 at block 1004. In place of the omitted interface adhesive 402, a fourth interface metal layer 610 is selectively deposited over the exposed surfaces of the molding compound 216 and the first underfill 214 using PVD and a stencil that exposes the molding compound 216 and the first underfill 214 on the package component 300. Like the first interface metal layer 602 and the second interface metal layer 604, the fourth interface metal layer 610 may include a metal or metal nitride, such as silver, gold, titanium, aluminum, titanium nitride, copper, or tin.

The present disclosure provides many embodiments. In one aspect, the present disclosure provides a package structure. The package structure includes a substrate, a package component bonded to the substrate and including a first die, a second die laterally spaced apart from the first die by an underfill, and a molding compound adjacent the first die and the second die, a lid disposed over the package component and the substrate, and an interface structure sandwiched between the package component and the lid. The interface structure includes an interface layer disposed over the underfill and the molding compound and a thermal interface material (TIM) layer over the interface layer, the first die and the second die.

In some embodiments, the interface layer includes a metal layer. In some implementations, a Young's modulus of the interface layer is smaller than a Young's modulus of the TIM layer. In some embodiments, a thermal conductivity of the TIM layer is greater than a thermal conductivity of the interface layer. In some embodiments, the interface layer includes a die attach film (DAF), silicone, polyimide, or epoxy. In some embodiments, the TIM layer includes beryllium oxide, aluminum oxide, zinc oxide, aluminum nitride, hexagonal boron nitride, copper, aluminum, diamond, graphene, or graphite. In some embodiments, the lid includes as aluminum (Al), copper (Cu), iron (Fe), nickel (Ni), cobalt (Co), an aluminum-copper alloy, an iron-nickel alloy, or an iron-nickel-cobalt alloy. In some instances, the TIM layer is spaced apart from the underfill and the molding compound by the interface layer.

In another aspect, the present disclosure provides a package structure. The package structure includes a substrate, a package component bonded to the substrate and including a first die, a second die laterally spaced apart from the first die by an underfill, and a molding compound adjacent the first die and the second die, a lid disposed over the package component and the substrate, and an interface structure sandwiched between the package component and the lid. The lid includes a convex surface partially extending into the interface structure.

In some embodiments, the interface structure includes a first metal layer over the package component and a thermal interface material (TIM) layer over the first metal layer. In some embodiments, the first metal layer is in direct contact with the underfill, the molding compound, the first die and the second die. In some embodiments, a thickness of the TIM layer is between about 50 times and about 100 times of a thickness of the first metal layer. In some embodiments, the TIM layer includes beryllium oxide, aluminum oxide, zinc oxide, aluminum nitride, hexagonal boron nitride, copper, aluminum, diamond, graphene, or graphite. In some embodiments, the interface structure further includes a second metal layer over the TIM layer such that the TIM layer is sandwiched between the first metal layer and the second metal layer. In some instances, the second metal layer includes silver (Ag), gold (Au), titanium (Ti), titanium nitride (TiN), copper (Cu), or tin (Sn).

In still another aspect, the present disclosure provides a method. The method includes bonding, to a front side of a substrate, a package component including a first die, a second die laterally spaced apart from the first die by an underfill, and a molding compound adjacent the first die and the second die, selectively dispensing an adhesive layer over top surfaces of the underfill and the molding compound, depositing a thermal interface material (TIM) over the adhesive layer, the first die, and the second die, after the depositing, placing a lid over the package component and the substrate, and curing the adhesive layer and the TIM.

In some embodiments, the depositing of the TIM includes depositing the TIM directly on top surfaces of the first die and the second die. In some embodiments, after the depositing of the TIM, the TIM is spaced apart from the top surfaces of the underfill and the molding compound by the adhesive layer. In some embodiments, the adhesive layer includes a die attach film (DAF), silicone, polyimide, or epoxy and the TIM includes beryllium oxide, aluminum oxide, zinc oxide, aluminum nitride, hexagonal boron nitride, copper, aluminum, diamond, graphene, or graphite. In some embodiments, the curing includes a curing temperature between about 100° C. and about 200° C. and a curing time between about 1 hour and about 2 hours.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a package component bonded to the package substrate and comprising:
a first die, and
a second die laterally spaced apart from the first die by an underfill;
a molding compound disposed along edges of the package component;
a lid bonded to the package substrate by way of an adhesive to enclose the package component; and
an interface structure sandwiched between the package component and the lid, the interface structure comprising:
a first interface metal layer interfacing the first die, the second die, the underfill, and the molding compound,
a thermal interface material (TIM) layer over the first interface metal layer, and
a second interface metal layer over the TIM layer to interface the lid.

2. The package structure of claim 1, wherein the first interface metal layer and the second interface metal layer comprise silver, gold, titanium, aluminum, titanium nitride, copper, or tin.

3. The package structure of claim 1, wherein the adhesive comprises a die attach film (DAF) gel, silicone, polyimide (PI), or epoxy.

4. The package structure of claim 1, wherein the TIM layer comprises beryllium oxide, aluminum oxide, zinc oxide, aluminum nitride, hexagonal boron nitride, copper, aluminum, diamond, graphene, or graphite.

5. The package structure of claim 1, wherein the lid comprises aluminum (Al), copper (Cu), iron (Fe), nickel (Ni), cobalt (Co), an aluminum-copper alloy, an iron-nickel alloy, or an iron-nickel-cobalt alloy.

6. The package structure of claim 1, wherein the package substrate comprises a printed circuit board (PCB).

7. The package structure of claim 1, wherein the lid includes a convex surface partially extending into the interface structure.

8. The package structure of claim 7, wherein the TIM layer and the second interface metal layer comprise a profile that accommodates the convex surface of the lid.

9. The package structure of claim 1, wherein the molding compound comprises polymer, resin, epoxy, silicon oxide (silica), aluminum oxide, or a combination thereof.

10. The package structure of claim 1, wherein the underfill comprises polymer or epoxy.

11. A package structure, comprising:
a printed circuit board (PCB);
a package component bonded to the PCB and comprising:
a high bandwidth memory (HBM) die, and
a system-on-chip (SoC) die laterally spaced apart from the HBM die by an underfill;
a molding compound disposed along edges of the package component;
a lid bonded to the PCB by way of an adhesive to enclose the package component; and
an interface structure sandwiched between the package component and the lid, the interface structure comprising:
a first interface metal layer interfacing the HBM die, the SoC die, the underfill, and the molding compound,
a thermal interface material (TIM) layer over the first interface metal layer, and
a second interface metal layer over the TIM layer to interface the lid, wherein the lid includes a convex surface partially extending into the interface structure.

12. The package structure of claim 11, wherein the TIM layer and the second interface metal layer comprise a profile that accommodates the convex surface of the lid.

13. The package structure of claim 11, further comprising:
at least one passive component mounted on the PCB,
wherein the at least one passive component is disposed between the package component and an edge of the lid.

14. The package structure of claim 11, wherein the first interface metal layer and the second interface metal layer comprise silver, gold, titanium, aluminum, titanium nitride, copper, or tin.

15. The package structure of claim 11, wherein the adhesive comprises a die attach film (DAF) gel, silicone, polyimide (PI), or epoxy.

16. The package structure of claim 11, wherein the TIM layer comprises beryllium oxide, aluminum oxide, zinc oxide, aluminum nitride, hexagonal boron nitride, copper, aluminum, diamond, graphene, or graphite.

17. A package structure, comprising:
a package substrate;
a package component bonded to the package substrate and comprising:
a first die, and
a second die laterally spaced apart from the first die by an underfill;
a molding compound disposed along edges of the package component;
a lid bonded to the package substrate by way of an adhesive to enclose the package component; and
an interface structure sandwiched between the package component and the lid, the interface structure comprising:
a first interface metal layer interfacing the first die, the second die, the underfill, and the molding compound;
a thermal interface material (TIM) layer over the first interface metal layer; and
a second interface metal layer over the TIM layer to interface the lid,
wherein the first interface metal layer and the second interface metal layer comprise silver, gold, titanium, aluminum, titanium nitride, copper, or tin,
wherein the TIM layer comprises beryllium oxide, aluminum oxide, zinc oxide, aluminum nitride, hexagonal boron nitride, copper, aluminum, diamond, graphene, or graphite.

18. The package structure of claim 17, wherein the lid includes a convex surface partially extending into the interface structure.

19. The package structure of claim 18, wherein the TIM layer and the second interface metal layer comprise a profile that accommodates the convex surface of the lid.

20. The package structure of claim 17, wherein the first interface metal layer and the second interface metal layer comprise a thickness between about 1 μm and about 2 μm.
